(19) United States
(12) Patent Application Publication
(10) Pub. No.: US 2021/0020652 A1
(43) Pub. Date: Jan. 21, 2021

(54) Using Metal Gate First Method to Build Three-Dimensional Non-Volatile Memory Devices

(71) Applicant: Weimin Li, (US)

(72) Inventor: Weimin Li, New Milford, CT (US)

(73) Assignee: Weimin Li, New Milford, CT (US)

(21) Appl. No.: 16/517,600

(22) Filed: Jul. 21, 2019

(51) Int. Cl. H01L 27/11582; H01L 27/11556; H01L 27/11524; H01L 27/1157

(52) U.S. Cl. CPC H01L 27/11582; H01L 27/1157; H01L 27/11524; H01L 27/11556

(57) ABSTRACT

A three-dimensional NAND memory system and method of making is disclosed. The three-dimensional NAND memory system may comprise a stack of horizontal layers and a vertical structure. The stack of horizontal layers may be formed on a semiconductor substrate. The stack of horizontal layers may comprise a plurality gate electrode layers alternating with a plurality of insulating layers. The gate electrode layer may comprise conductive lines alternate with insulating lines. The insulating lines may be formed of insulating materials. The conductive lines are formed of a metal comprising W. The vertical structure may extend vertically through the stack of horizontal layers. The vertical structure may comprise a blocking dielectric layer, a charge storage layer, a tunnel dielectric layer, and a vertical channel structure. The charge storage layer may be formed over the blocking dielectric layer. The tunnel dielectric layer may be formed over the charge storage layer. The tunnel dielectric layer may be sandwiched between the vertical channel structure and the charge storage layer. There is no metal nitride layer in the vertical structure between the stack of horizontal layers and blocking dielectric layer.

### RELATED APPLICATIONS

This application claims priority to and benefit from a PCT application No. PCT/US18/14408, which was filed on Jan. 19, 2018, which claims priority to and benefit from a U.S. Provisional Application No. 62/448,677, filed on Jan. 20, 2017, which is hereby incorporated by reference herein in its entirety.

### TECHNICAL FIELD

The present disclosure relates generally to semiconductor devices and non-volatile memory transistor, and more particularly to three-dimensional non-volatile memory devices and methods of fabrications.

### BACKGROUND

Advances in semiconductor fabrication technology continue to enable physical scaling of semiconductor integrated circuit devices. One of the technological advances in new generations of semiconductor devices, e.g., memory device technologies at advanced technology nodes (e.g., nodes below 10 nm), includes three-dimensional (3D) memory devices or vertical non-volatile memory devices, such as, for example, 3D NAND flash memory devices. However, some 3D NAND flash memory technologies can have a number of disadvantages, such as: limited scalability (scaling the plug diameter is difficult), a need for high voltages (typically higher than 10V, even higher than 15V) and/or costly to manufacture.

In view of the foregoing, a need exists for an efficient or cost-effective method of fabricating three-dimensional NAND.

### SUMMARY

According to a first aspect, a method of fabricating three-dimensional NAND comprises steps of forming a stack of alternating layers of a first material and a second material over a substrate, wherein the first material comprises an insulating material and wherein the second material comprises a conductive material; forming through the stack of horizontal layers a vertical opening thereby exposing the semiconductor substrate and exposing the stack of horizontal layers on a sidewall of the vertical opening; forming a blocking dielectric layer along the sidewall of the vertical opening; forming a charge storage layer over the blocking dielectric layer in the vertical opening; forming a tunnel dielectric layer over the charge storage layer in the vertical opening; forming a semiconductor layer over the tunnel dielectric layer in the vertical opening; filling the vertical opening with an insulating material over the semiconductor layer; creating a word line mask on a top surface of the stack; etching unmasked areas through the stacks to form trenches along the word lines; and filling the trenches with the insulating material.

In certain aspects, the semiconductor layer may include polycrystalline silicon.

In certain aspects, the charge storage layer may include silicon nitride.

In certain aspects, the first material may include silicon oxide.

In certain aspects, the second material may be selected from the group consisting of W, Mo, Ru, Ni, Al, Ti, Ta, their nitrides, and the combinations thereof.

In certain aspects, the blocking dielectric layer may include aluminum oxide.

In certain aspects, the tunnel dielectric layer may include silicon oxide.

In certain aspects, the second material may include W, for example.

In certain aspects, the insulating material may include silicon oxide.

In certain aspects, the layer of the first or second material may be less than about 80 nm thick, for example.

In certain aspects, the layer of the first or second material may be less than about 70 nm thick, for example.

In certain aspects, the layer of the first or second material may be less than about 60 nm thick, for example.

In certain aspects, the layer of the first or second material may be less than about 50 nm thick, for example.

In certain aspects, the second material of the stacks is not completely removed after the formation of the stacks of alternative layers.

In certain aspects, the second material of the stacks is not completely replaced after the formation of the stacks of alternative layers.

In certain aspects, the second material of the stacks is not a sacrificial material.

According to a second aspect, a method of fabricating three-dimensional NAND comprises steps of forming a stack of alternating layers of a first material and a second material over a substrate, wherein the first material comprises an insulation material and wherein the second material comprises a conductive material; forming through the stack of horizontal layers a vertical opening thereby exposing the semiconductor substrate and exposing the stack of horizontal layers on a sidewall of the vertical opening; selectively removing a part of the second material of the stack through the vertical opening to form a recess; forming an oxide layer along the sidewall of the vertical opening; filling a semiconductor material into horizontal trenches from the recess; removing the semiconductor layer on a vertical sidewall of the vertical opening; forming a tunnel dielectric layer over the sidewall of the vertical opening; forming a semiconductor layer over the tunnel dielectric layer in the vertical opening; filling the vertical opening with an insulating material over the semiconductor layer; creating a word line mask on a top surface of the stack; etching unmasked areas through the stacks to form trenches along the word lines; and filling the trenches with the insulating material.

According to a third aspect, a method of fabricating three-dimensional NAND may comprise steps of forming a stack of alternating layers of a first material and a second material over a substrate, wherein the first material comprises an insulation material, and wherein the second material comprises a conductive material, wherein the second material of the stacks is not a sacrificial material and it is not completely removed or replaced after the formation of the stacks of alternative layers.

According to a fourth aspect, a memory device may include a stack of horizontal layers, a vertical structure. The vertical structure may include a charge storage layer, a tunnel dielectric layer, and a vertical channel structure. The stack of horizontal layers may be formed on a semiconductor substrate. The stack of horizontal layers may include a plurality gate electrode layers alternating with a plurality of insulating layers. The gate electrode layer may comprise only one conductive material.

The charge storage layer may be formed over the blocking dielectric layer. The tunnel dielectric layer may be formed over the charge storage layer. The tunnel dielectric layer may be sandwiched between the vertical channel structure and the charge storage layer. There is no layer between vertical blocking material, and horizontal gate electrode material. In certain aspects, the insulating lines may be formed of insulating materials.

In certain aspects, the insulating material may include silicon oxide.

In certain aspects, the conductive lines may be formed of a metal.

In certain aspects, the conductive lines may be formed of a metal which may be selected from the group consisting of Cu, Al, Ti, W, Ni, Au, TiN, TaN, TaC, NbN, RuTa, Co, Ta, Mo, Pd, Pt, Ru, Ir, Ag and combinations thereof.

In certain aspects, the vertical channel structure may be formed of a semiconductor material.

In certain aspects, the metal nitride layer may include titanium nitride.

In certain aspects, the conductive lines may be formed of a metal comprising W.

### DESCRIPTION OF THE DRAWINGS

These and other advantages of the present invention may be readily understood with the reference to the following specifications and attached drawings wherein:

FIG. 1 illustrates a cross-sectional view of an exemplary three-dimensional memory device in accordance with an aspect of the present disclosure.

FIG. 2 illustrates a cross-sectional view of a stack of alternating layers of a first material and a second material.

FIG. 3 illustrates a flow chart of a method of fabricating a three-dimensional NAND according to one embodiment.

FIG. 4 continually illustrates the flow chart of the method according to FIG. 3.

FIG. 5 illustrates a flow chart of a method of fabricating a three-dimensional NAND according to another embodiment.

FIG. 6 continually illustrates the flow chart of the method according to FIG. 5.

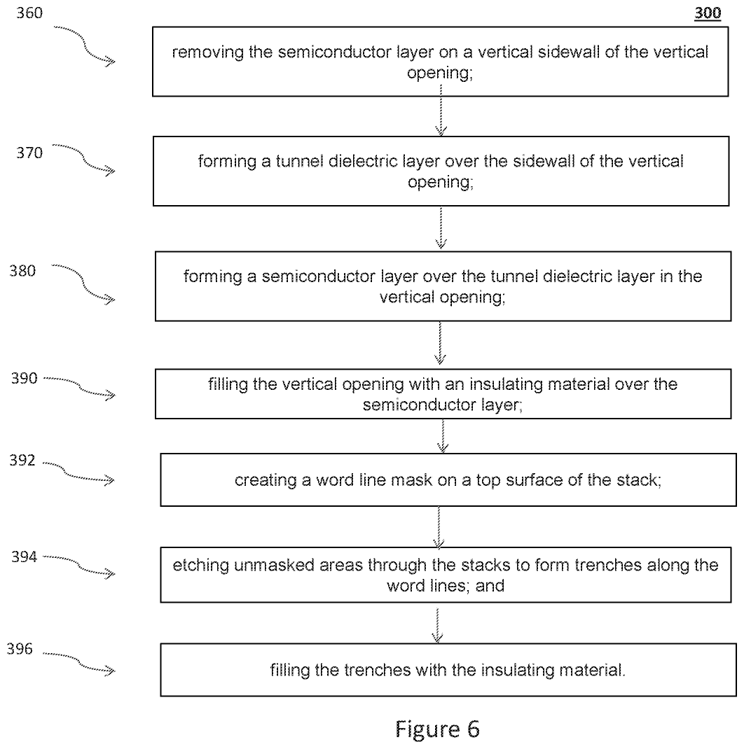

FIG. 7 illustrates a flow chart of a method of fabricating a three-dimensional NAND according to yet another embodiment.

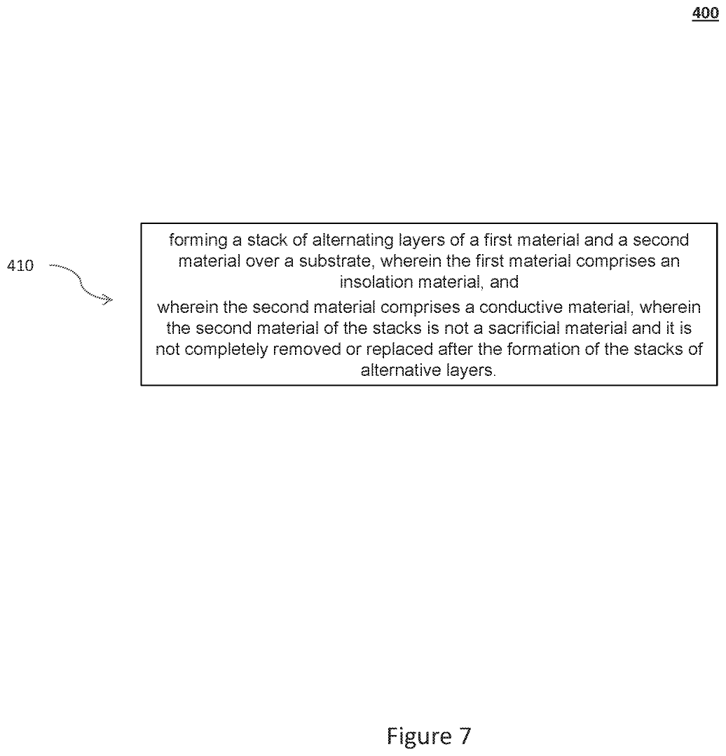

### DETAILED DESCRIPTION

Preferred embodiments of the present disclosure may be described hereinbelow with reference to the accompanying drawings. In the following description, well-known functions or constructions are not described in detail because they may obscure the disclosure in unnecessary detail. For this disclosure, the following terms and definitions shall apply.

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments.

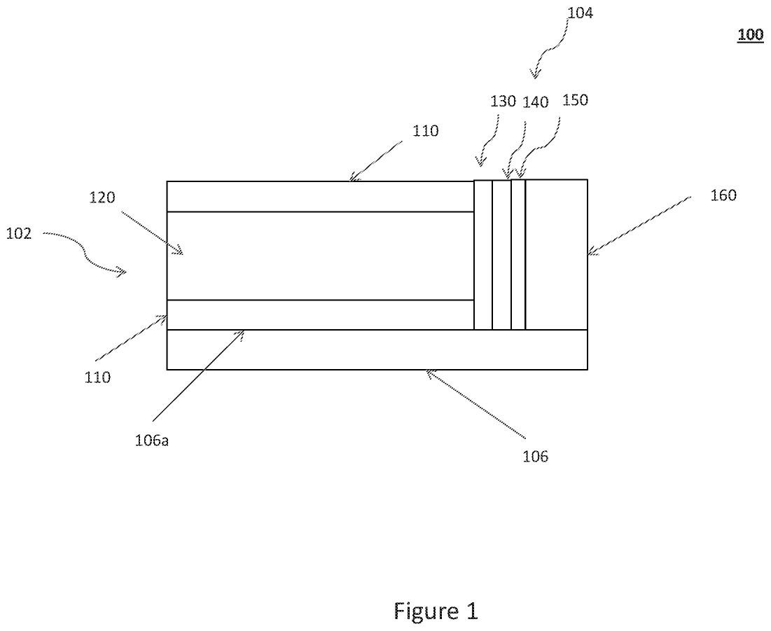

Embodiments include three dimensional NAND strings and methods of making these three-dimensional NAND strings. As shown in FIG. 1, a memory device 100 may include a stack of horizontal layers 102, a vertical structure 104. The vertical structure 104 may include a blocking dielectric layer 130, a charge storage layer 140, a tunnel dielectric layer 150, and a vertical channel structure 160. The stack of horizontal layers 102 may be formed on a substrate 106. The stack of horizontal layers 102 may include a plurality gate electrode layers 120 alternating with a plurality of insulating layers 110. The gate electrode layer 120 may comprise conductive lines alternate with insulating lines.

The charge storage layer 140 may be formed over the blocking dielectric layer 130. The tunnel dielectric layer 150 may be formed over the charge storage layer 140. The tunnel dielectric layer 150 may be sandwiched between the vertical channel structure 160 and the charge storage layer 140. There may be no metal nitride layer, such as titanium nitride, for example, in the vertical structure 104 between the stack of horizontal layers 102 and blocking dielectric layer 130.

In one embodiment, the memory device 100 may be a monolithic three-dimensional memory array. In another embodiment, the memory device 100 may not be a monolithic three-dimensional memory array.

A monolithic three-dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and adhering the memory levels atop each other. The substrates may be thinned or removed from the memory levels before bonding, but as the memory levels are initially formed over separate substrates, such memories are not true monolithic three-dimensional memory arrays.

In some embodiments, the vertical channel structure 160 of the monolithic three-dimensional NAND 100 may have at least one end portion extending substantially perpendicular to a major surface 106a of a substrate 106, as shown in FIG. 1. “Substantially perpendicular to” (or “substantially parallel to”) means within about 0-10°. For example, the vertical channel structure 160 may have a pillar shape and the entire pillar-shaped vertical channel structure extends substantially perpendicularly to the major surface 106a of the substrate 106, as shown in FIG. 1.

Alternatively, the vertical channel structure 160 may have various shapes, which may not be substantially perpendicular to the major surface 106a of the substrate 106. The blocking dielectric layer 130, the charge storage layer 140 and the tunnel dielectric layer 150 may have various shapes, which may not be substantially perpendicular to the major surface 106a of the substrate 106.

The substrate 106 can be any semiconducting substrate known in the art, such as monocrystalline silicon, IV-IV compounds such as silicon-germanium or silicon-germanium-carbon, III-V compounds, II-VI compounds, epitaxial layers over such substrates, or any other semiconducting or non-semiconducting material, such as silicon oxide, glass, plastic, metal or ceramic substrate. The substrate 106 may include integrated circuits fabricated thereon, such as driver circuits for a memory device.

Any suitable semiconductor materials can be used for the vertical channel structure 160, for example silicon, germanium, silicon germanium, or other compound semiconductor materials, such as III-V, II-VI, or conductive or semi conductive oxides, etc. The semiconductor material may be amorphous, polycrystalline or single crystal. The semiconductor channel material may be formed by any suitable deposition methods. For example, in one embodiment, the vertical channel structure 160 is deposited by low pressure chemical vapor deposition (LPCVD). In some other embodiments, the semiconductor channel material may be a recrystallized polycrystalline semiconductor material formed by recrystallizing an initially deposited amorphous semiconductor material.

The blocking dielectric layer 130 is located adjacent to the control gate(s) and may surround the control gate electrode layers 120, as shown in FIG. 1. Alternatively, the blocking dielectric layer 130 may be located only adjacent to an edge (i.e., minor surface) of each control gate electrode 120. The blocking dielectric layer 130 may comprise a layer having plurality of blocking dielectric segments located in contact with a respective one of the pluralities of control gate electrodes 102. Alternatively, the blocking dielectric 130 may be a straight, continuous layer, as shown in FIG. 1.

The charge storage layer 140 may comprise one or more continuous layers which extend the entire length of the memory cell portion of the NAND string, as shown in FIG. 1. For example, the charge storage layer 140 may comprise an insulating charge trapping material, such as a silicon nitride layer.

Alternatively, the charge storage layer 140 may comprise a plurality of discrete charge storage regions. The discrete charge storage regions may comprise a plurality of vertically spaced apart, conductive (e.g., metal such as tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), or semiconductor (e.g., polysilicon) floating gates. Alternatively, the discrete charge storage regions may comprise an insulating charge trapping material, such as silicon nitride segments.

The tunnel dielectric layer 150 of the monolithic three-dimensional NAND string 100 is located between charge storage region 140 and the vertical channel structure 160.

The blocking dielectric layer 130 and the tunnel dielectric layer 150 may be independently selected from any one or more same or different electrically insulating materials, such as silicon oxide, silicon nitride, silicon oxynitride, or other insulating materials. The blocking dielectric layer 130 and/or the tunnel dielectric layer 150 may include multiple layers of silicon oxide, silicon nitride and/or silicon oxynitride (e.g., ONO layers) and/or high-k materials such as aluminum oxide, hafnium oxide or combinations thereof. The blocking dielectric layer 130 may comprise a plurality of metal oxide clam shaped regions and the plurality of control gate electrodes 120 are located in respective openings in respective metal oxide clam shaped regions.

In some embodiments, the insulating layers 110 may comprise silicon oxide, for example. The conductive lines of gate electrode 120 may be formed of a metal, which may be selected from the group consisting of Cu, Al, Ti, W, Ni, Au, TiN, TaN, TaC, NbN, RuTa, Co, Ta, Mo, Pd, Pt, Ru, Ir, Ag and combinations thereof. More preferably, the conductive lines of gate electrode 120 may be formed of a metal comprising W.

Charge Trapping Type of Stacks

Charge Trap is a semiconductor memory technology used in creating non-volatile NAND flash memory. The technology differs from the more conventional floating-gate MOSFET technology in that it uses a silicon nitride film to store electrons rather than the doped polycrystalline silicon typical of a floating gate structure. This approach allows memory manufacturers to reduce manufacturing costs five ways: fewer process steps are required to form a charge storage node; smaller process geometries can be used (therefore reducing chip size and cost); multiple bits can be stored on a single flash memory cell; improved reliability; higher yield since the charge trap is less susceptible to point defects in the tunnel oxide layer.

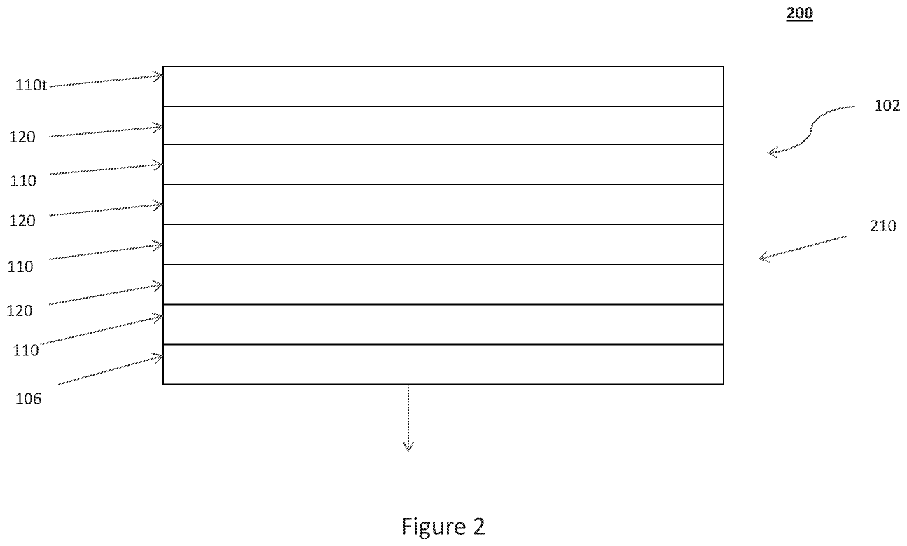

In one embodiment, as shown in FIG. 2, a method 200 of fabricating a three-dimensional NAND 100 may be carried out by forming a stack of alternative layers 102 of a first material, such as an insulating material/layer 110, for example, and a second material, including a conductive material, such as a gate electrode layer 120, for example, over a substrate 106 in a step 210. In one embodiment, the first material may include silicon oxide, and the second material may be selected from the group consisting of W, Mo, Ru, Ni, Al, Ti, Ta, their nitrides, and the combinations thereof. In another embodiment, the second material may include W, for example. In one embodiment, the second material of the stacks is not completely removed after the formation of the stacks of alternative layers. In another embodiment, the second material of the stacks is not completely replaced after the formation of the stacks of alternative layers. In yet another embodiment, the second material of the stacks is not a sacrificial material.

If desired, a top insulating layer 110t may have a greater thickness and/or a different composition from the other insulating layers 110, shown in FIG. 2. For example, the top insulating layer 110t may comprise a cover silicon oxide layer made using a TEOS source while the remaining layers 110 may comprise thinner silicon oxide layers that may use a different source. In one embodiment, the layer of the first or second material may be less than about 80 nm thick, for example. In one embodiment, the layer of the first or second material may be less than about 70 nm thick, for example. In further embodiment, the layer of the first or second material may be less than about 60 nm thick, for example. In additional embodiment, the layer of the first or second material may be less than about 50 nm thick, for example.

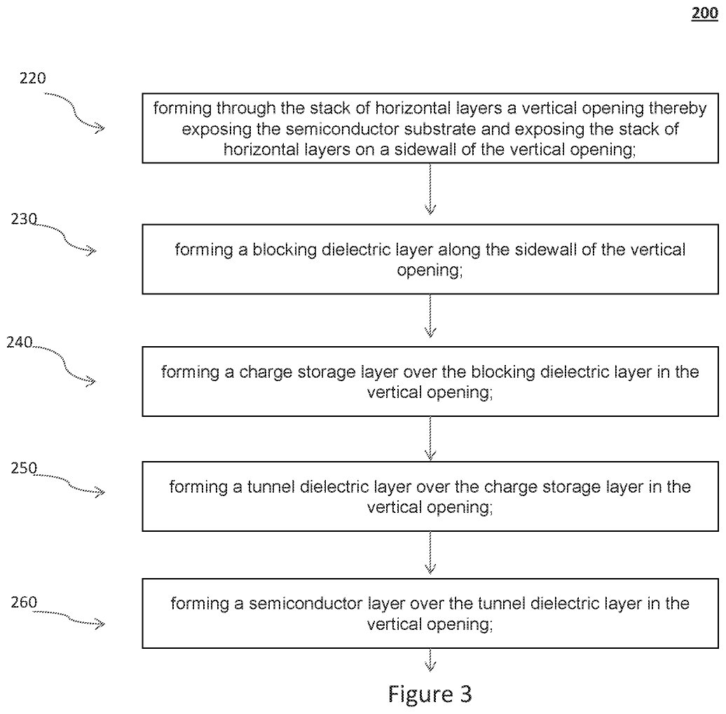

As shown in FIG. 3, the method 200 may be further carried out by forming through the stack of horizontal layers a vertical opening thereby exposing the semiconductor substrate and exposing the stack of horizontal layers on a sidewall of the vertical opening in a step 220, as shown in FIG. 3. The step 220 may include forming the vertical openings by RIE or another suitable etching method. The stack of horizontal layers 102 includes a plurality of vertical openings.

The method 200 may be further carried out by forming a blocking dielectric layer along the sidewall of the vertical opening in a step 230; forming a charge storage layer over the blocking dielectric layer in the vertical opening in a step 240; and forming a tunnel dielectric layer over the charge storage layer in the vertical opening in a step 250. In one embodiment, the blocking dielectric layer may comprise a metal oxide, such as aluminum oxide, for example. In one embodiment, the charge storage layer comprises silicon nitride, for example. In one embodiment, the tunnel dielectric layer comprises silicon oxide, for example.

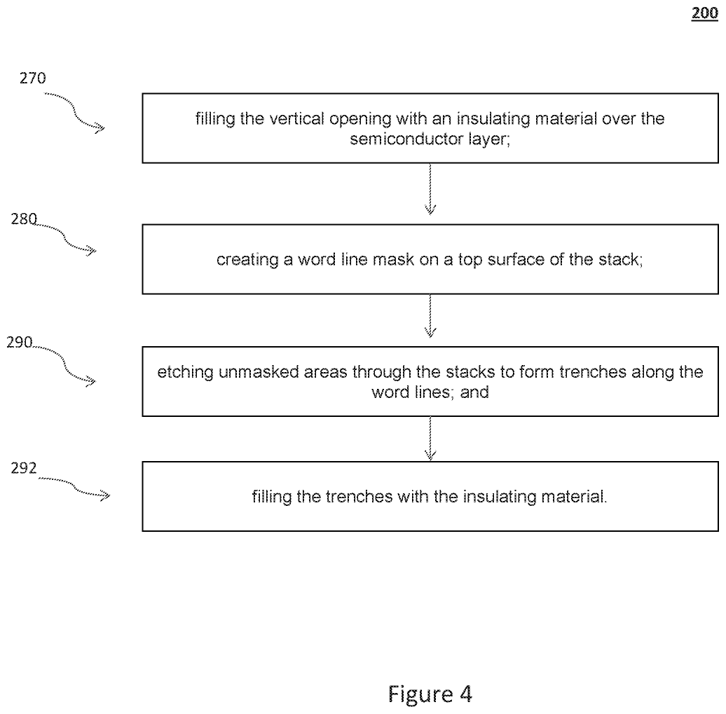

The method 200 may be further carried out by forming a semiconductor layer over the tunnel dielectric layer in the vertical opening in a step 260 shown in FIG. 3; filling the vertical opening with an insulating material over the semiconductor layer in a step 270 shown in FIG. 4. The blocking dielectric layer, the charge storage layer, or the tunnel dielectric layer may be formed via by atomic layer deposition (ALD), chemical vapor deposition (CVD), or physical vapor deposition (PVD), for example. In one embodiment, the semiconductor layer comprises polycrystalline silicon, for example.

The semiconductor layer may be formed by a desired method. For example, the semiconductor layer may be formed by depositing semiconductor (e.g., polysilicon) material in the vertical opening and over the tunnel dielectric layer, followed by a step of removing the upper portion of the deposited semiconductor layer by chemical mechanical polishing (CMP) or etch back using top surface of the stack as a polish stop or etch stop.

In some embodiments, a single crystal silicon or polysilicon vertical semiconductor layer may be formed by metal induced crystallization (“MIC”, also referred to as metal induced lateral crystallization) without a separate masking step. The MIC method provides full channel crystallization due to lateral confinement of the channel material in the vertical opening.

In the MIC method, an amorphous or small grain polysilicon semiconductor (e.g., silicon) layer can be first formed in the vertical opening and over the tunnel dielectric layer, followed by forming a nucleation promoter layer over the semiconductor layer. The nucleation promoter layer may be a continuous layer or a plurality of discontinuous regions. The nucleation promoter layer may comprise any desired polysilicon nucleation promoter materials, for example but not limited to nucleation promoter materials such as Ge, Ni, Pd, Al or a combination thereof.

The amorphous or small grain semiconductor layer can then be converted to a large grain polycrystalline or single crystalline semiconductor layer by recrystallizing the amorphous or small grain polycrystalline semiconductor. The recrystallization may be conducted by a low temperature (e.g., 300 to 600° C.) anneal.

The semiconductor layer, such as polycrystalline silicon, may be doped with As, B, or other semiconductor. The doping process may be achieved by adding dopant containing gases during the polycrystalline silicon deposition.

The method 200 may be further carried out by creating a word line mask on a top surface of the stack in a step 280; etching unmasked areas through the stacks to form trenches along the word lines in a step 290 and filling the trenches with the insulating material in a step 292. The word lines are substantially perpendicular to bit lines. In one embodiment, the masking material may comprise silicon oxide, for example. In one embodiment, parallel trenches were created through the stacks of alternating layers of first material and a second material. Insulating materials, such as polycrystalline silicon, for example, may be filled and thus parallel conductive lines may be formed for each alternating layer.

The method 200 may be further carried out by chemical mechanical polishing (CMP) to remove the semiconductor layer on the top surface of the stack and planarizing the top surface after the chemical mechanical polishing. The removal may be conducted by selectively wet etching the remaining nucleation promoter layer and any formed silicide in the top of layer following by CMP of the top of silicon layer using the top of the stacks as a stop.

Floating Gate Type of Stack.

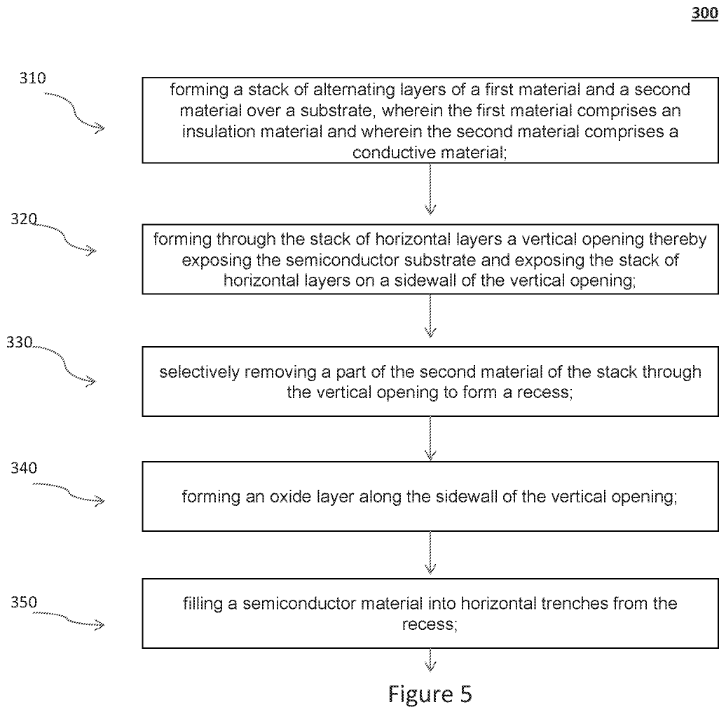

In another embodiment, as shown in FIG. 5, a method 300 of fabricating a three-dimensional NAND may be carried out by forming a stack of alternating layers of a first material and a second material over a substrate, wherein the first material comprises an insulation material and wherein the second material comprises a conductive material in a step 310 (shown in FIG. 2 as well). The method 300 may be further carried out by forming through the stack of horizontal layers a vertical opening thereby exposing the semiconductor substrate and exposing the stack of horizontal layers on a sidewall of the vertical opening in a step 320.

The method 300 may further include a step 330 of selectively removing a part of the second material, such as W, of the stack through the vertical opening to form a recess. The selectively removing a part of the second material may be done via a wet etch, such as wet chemical etch. The method 300 may be further carried out by forming an oxide layer along the sidewall of the vertical opening in a step 340 and filling a semiconductor material into horizontal trenches from the recess in a step 350. The oxide, such as aluminum oxide, silicon oxide, or other suitable dielectrics may be deposited using atomic layer deposition (ALD).

The method 300 may be further carried out by removing the semiconductor layer, such as polycrystalline silicon, on a vertical sidewall of the vertical opening in a step 360. The removal in the step 360 may be done by dry reactive etching while the polycrystalline silicon in the horizontal trenches may remain to form as a floating gate.

The method 300 may include a step 370 of forming a tunnel dielectric layer over the sidewall of the vertical opening. Plasma may be used to remove the oxide at the bottom of the vertical opening to expose the semiconductor substrate materials before the step 380 of forming a semiconductor layer over the tunnel dielectric layer in the vertical opening. The method 300 may further include filling the vertical opening with an insulating material over the semiconductor layer in a step 390.

The method 300 may be further carried out by creating a word line mask on a top surface of the stack in a step 392; etching unmasked areas through the stacks to form trenches along the word lines in a step 394 and filling the trenches with the insulating material in a step 396. In one embodiment, the masking material may comprise silicon oxide, for example. In one embodiment, parallel trenches were created through the stacks of alternating layers of first material and a second material. Insulating materials, such as polycrystalline silicon, for example, may be filled and thus parallel conductive lines may be formed for each alternating layer.

The method 300 may be further carried out by chemical mechanical polishing (CMP) to remove the semiconductor layer on the top surface of the stack and planarizing the top surface after the chemical mechanical polishing. The removal may be conducted by selectively wet etching the remaining nucleation promoter layer and any formed silicide in the top of layer following by CMP of the top of silicon layer using the top of the stacks as a stop.

In further another embodiment, a method 400 may include forming a stack of alternating layers of a first material and a second material over a substrate in a step 410. The first material may comprise an insulation material. The second material may comprise a conductive material. The second material of the stacks may not be a sacrificial material and may not be completely removed or replaced after the formation of the stacks of alternative layers.

In the method 400, the material layer may comprise silicon oxides. The second material may comprise a metal or metal nitride.

The above-cited patents and patent publications are hereby incorporated by reference in their entirety. Although various embodiments have been described with reference to a particular arrangement of parts, features, and like, these are not intended to exhaust all possible arrangements or features, and indeed many other embodiments, modifications, and variations may be ascertainable to those of skill in the art. Thus, it is to be understood that the invention may therefore be practiced otherwise than as specifically described above.

What is claimed is:

1. A method of fabricating a three-dimensional NAND, comprising:
forming a stack of alternating layers of a first material and a second material over a substrate, wherein the first material comprises an insulating material and wherein the second material comprises a conductive material;
forming through the stack of horizontal layers a vertical opening thereby exposing the semiconductor substrate and exposing the stack of horizontal layers on a sidewall of the vertical opening;
forming a blocking dielectric layer along the sidewall of the vertical opening;
forming a charge storage layer over the blocking dielectric layer in the vertical opening;
forming a tunnel dielectric layer over the charge storage layer in the vertical opening;
forming a semiconductor layer over the tunnel dielectric layer in the vertical opening;
filling the vertical opening with an insulating material over the semiconductor layer;
creating a word line mask on a top surface of the stack;
etching unmasked areas through the stacks to form trenches along the word lines; and
filling the trenches with the insulating material.

2. The method of claim 1, wherein the semiconductor layer comprises polycrystalline silicon.

3. The method of claim 1, wherein the first material comprises silicon oxide.

4. The method of claim 1, wherein the charge storage layer comprises silicon nitride.

5. The method of claim 1, wherein the blocking dielectric layer comprises aluminum oxide.

6. The method of claim 1, wherein the tunnel dielectric layer comprises silicon oxide.

7. The method of claim 1, wherein the second material is selected from the group consisting of W, Mo, Ru, Ni, Al, Ti, Ta, their nitrides, and the combinations thereof.

8. The method of claim 7, wherein the second material comprises W.

9. The method of claim 1, wherein the insulating material comprises silicon oxide.

10. The method of claim 1, wherein the layer of the first or second material is less than about 80 nm thick.

11. The method of claim 10, wherein the layer of the first or second material is less than about 50 nm thick.

12. The method of claim 1, wherein the second material of the stacks is not completely removed after the formation of the stacks of alternative layers.

13. The method of claim 1, wherein the second material of the stacks is not completely replaced after the formation of the stacks of alternative layers.

14. The method of claim 1, wherein the second material of the stacks is not a sacrificial material.

15. A method of fabricating three-dimensional NAND, comprising:
forming a stack of alternating layers of a first material and a second material over a substrate, wherein the first material comprises an insulation material, and
wherein the second material comprises a conductive material, wherein the second material of the stacks is not a sacrificial material and it is not completely removed or replaced after the formation of the stacks of alternative layers.

16. The method of claim 15, wherein the first material layer comprises silicon oxides and the second material comprise a metal or metal nitride.

17. A memory device, comprising:
a stack of horizontal layers formed on a substrate, the stack of horizontal layers comprising a plurality gate electrode layers alternating with a plurality of insulating layers, wherein the gate electrode layer comprises one conductive material;
a vertical structure extending vertically through the stack of horizontal layers, the vertical structure comprising a blocking dielectric layer;
a charge storage layer formed over the blocking dielectric layer;
a tunnel dielectric layer formed over the charge storage layer; and
a vertical channel structure, wherein the tunnel dielectric layer is sandwiched between the vertical channel structure and the charge storage layer, wherein there is no there is no layer between vertical blocking material, and horizontal gate electrode material.

18. The memory device of claim 17, wherein the insulating layers comprise silicon oxide.

19. The memory device of claim 17, wherein the conductive lines are formed of a metal.

20. The memory device of claim 17, wherein the conductive lines are formed of a metal selected from the group consisting of Cu, Al, Ti, W, Ni, Au, TiN, TaN, TaC, NbN, RuTa, Co, Ta, Mo, Pd, Pt, Ru, Ir, Ag and combinations thereof.
